(19) United States
(12) Patent Application Publication
(10) Pub. No.: US 2013/0240925 A1
(43) Pub. Date: Sep. 19, 2013

(54) LIGHT EMITTING DIODE PACKAGE AND METHOD OF MANUFACTURING THE SAME

(71) Applicant: CHIH-CHEN LAI, Tu-Cheng (TW)

(72) Inventor: CHIH-CHEN LAI, Tu-Cheng (TW)

(73) Assignee: HON HAI PRECISION INDUSTRY CO., LTD., Tu-Cheng (TW)

(21) Appl. No.: 13/472,419

(22) Filed: May 15, 2012

(30) Foreign Application Priority Data
Mar. 16, 2012 (TW) 101109103

(51) Int. Cl. H01L 33/50

(52) U.S. Cl. 257/98; 438/27; 257/E33.061

(57) ABSTRACT

An LED package includes a base, an LED chip disposed on the base, a liquid heat conducting layer and a sealing member. The LED chip is sealed from liquid. The liquid heat conducting layer surrounds and covers the sealed LED chip. The sealing member is arranged on the substrate and encloses and seals the liquid heat conducting layer therein. The LED chip is sealed by a phosphor layer on a top surface thereof and a heat conductive layer on a side surface thereof.

### BACKGROUND

1. Technical Field

The disclosure relates to light emitting diode (LED) packages, and particularly to an LED package with great heat dissipating capability and a method of manufacturing the LED package.

2. Discussion of Related Art

LEDs' many advantages, such as high luminosity, low operational voltage, low power consumption, compatibility with integrated circuits, easy driving, long term reliability, and environmental friendliness have promoted their wide use as a lighting source.

A typical LED package includes a substrate, an LED arranged on the substrate, an annular reflecting cup disposed on the substrate and surrounding the LED chip, and an encapsulant received in the reflecting cup and covering the LED. However, it is well known that heat is generated by the LED chip during operation. If the LED package is used in a state of high temperature for a long time, the life thereof is dramatically shortened.

Therefore, what is needed is an LED package which can overcome the described limitations.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a schematic, cross-sectional view of an LED package according to an exemplary embodiment of the present disclosure.

FIGS. 2 to 5 are cross-sectional views showing different steps of an embodiment of a method for manufacturing the LED package of FIG. 1.

### DETAILED DESCRIPTION OF EMBODIMENTS

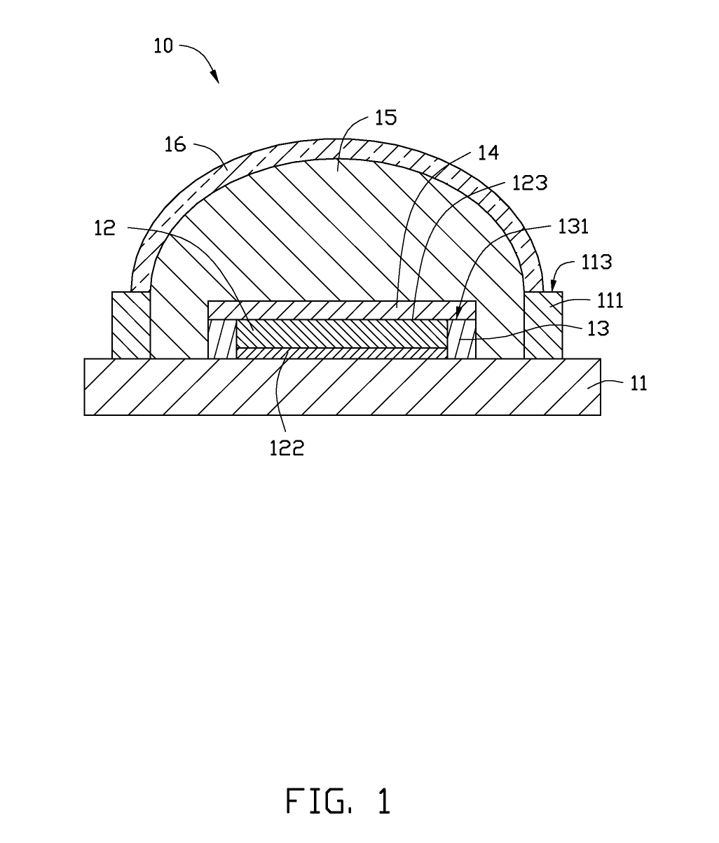

Referring to FIG. 1, an LED package 10 in accordance with an exemplary embodiment of the present disclosure is illustrated. The LED package 10 includes a substrate 11, an LED chip 12 mounted on the substrate 11, a side conductive layer 13 surrounding the LED chip 12, a phosphor layer 14 arranged on the LED chip 12, a sealing member 16 surrounding and covering the LED chip 12, and a liquid heat conductive layer 15 sealed in the sealing member 16.

In the present embodiment, the substrate 11 is a rectangular plate made of polyphthalamide (PPA). An annular side conductive plate 111 is arranged on the substrate 11. The side conductive plate 111 is made of metal. Alternatively, the side conductive plate 111 can be made of polyphthalamide (PPA), and can be integrally formed with the substrate 11 as a single piece. In the present embodiment, a circuit layer (not shown) is arranged on the substrate 11.

A connecting layer 122 is mounted on the substrate 11 and received in the side conductive plate 111. In the present embodiment, the connecting layer 122 is made of a good heat conductive material, such as copper, aluminum or alloy thereof, for transferring heat from the LED chip 12 to the substrate 11 efficiently. The LED chip 12 is mounted on the connecting layer 122 via eutectic bonding. The LED chip 12 is electrically connected to an external power supply via the circuit layer. The LED chip 12 includes a light emitting surface 123 away from the substrate 11.

The side conductive layer 13 is annular and arranged on the substrate 11 for surrounding side surfaces of the LED chip 12. In the present embodiment, the light emitting surface 123 is substantially coplanar with a top surface 131 of the side conductive layer 13. The side conductive layer 13 is made of a good heat conductive material, for transferring heat from the LED chip 12 to the liquid heat conductive layer 15 efficiently. In the present embodiment, the side conductive layer 13 is made of copper. The phosphor layer 14 is arranged on the light emitting surface 123 of the LED chip 12 and the top surface 131 of the side conductive layer 13. The phosphor layer 14 can be selected from garnet phosphor, silicate phosphor, or sulphide phosphor. The phosphor layer 14, the side conductive layer 13 and the substrate 11 cooperatively seal the LED chip 12 therebetween. As a result, a sealed LED chip 12 is formed for preventing damage of the LED chip 12 due to entrance of the liquid heat conductive layer 15 into the LED chip 12. Alternatively, the LED chip 12 can be sealed by a typical method, such as coating a waterproof layer or a sealant thereon.

The sealing member 16 has an arc shaped and engaged with an upper surface 113 of the side conductive plate 111 to form a sealed chamber among the sealing member 16, the substrate 11 and the side conductive plate 111. In the present embodiment, the sealing member 16 is made of transparent material, such as glass. The liquid heat conductive layer 15 is sealed in the sealing member 16 and covers the sealed LED chip 12. The liquid heat conductive layer 15 is made of a good heat conductive material. The liquid heat conductive layer 15 is liquid, and can transfer heat generated from the LED chip 12 to the ambient atmosphere via the sealing member 16.

A part of heat generated from the LED chip 12 is transferred to the ambient atmosphere via the liquid heat conductive layer 15, and the other part of heat generated from the LED chip 12 is transferred to the substrate 11 via the connecting layer 122, and then dissipate to the ambient atmosphere; therefore, a heat dissipating capability, and lifespan of the LED package 10 is improved. In addition, since the sealing member 16 is made of glass, it can improve the mechanical strength of the LED package 10.

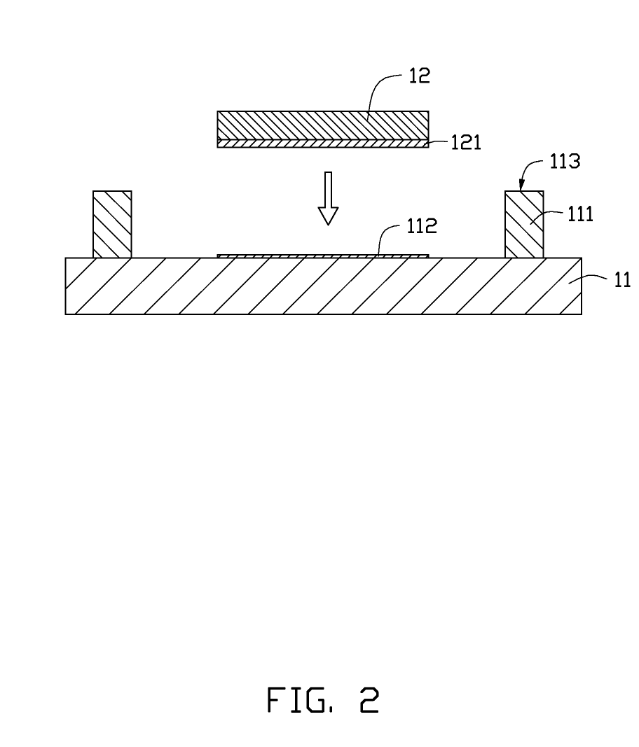

Referring to FIGS. 2-5, a method for manufacturing the LED package 10 in accordance with an exemplary embodiment is also disclosed, and includes:

Step 1: referring to FIG. 2, providing a substrate 11, mounting an annular side conductive plate 111 on the substrate 11, and forming a first metal layer 112 on the substrate 11 wherein the first metal layer 12 is received in a space surrounded by the side conductive plate 111. In the present embodiment, a circuit layer (not shown) is arranged on the substrate 11. The side conductive plate 111 has an upper surface 113 away from the substrate 11.

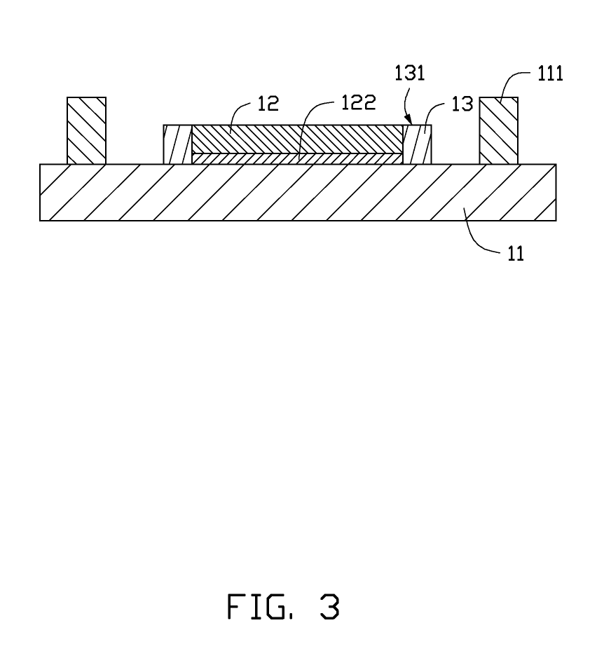

Step 2: referring to FIG. 3 also, providing an LED chip 12, forming a second metal layer 121 on a bottom surface of the LED chip 12, and then mounting the LED chip 12 on the first metal layer 112 to make the second metal layer 121 connected to the first metal layer 112 by eutectic bonding thereby to secure the LED chip 12 on the substrate 11. In the present embodiment, the first metal layer 112 and the second metal layer 121 each are made of a good heat conductive material, such as copper, aluminum or alloy thereof, for transferring heat from the LED chip 12 to the substrate 11 efficiently. The first metal layer 112 is cooperated with the second metal layer 121 to form a connecting layer 122 for dissipating heat generated from the LED chip 12. The LED chip 12 is electrically connected to an external power supply via the circuit layer. The LED chip 12 has a light emitting surface 123 away from the substrate 11.

Step 3: forming an annular side conductive layer 13 surrounding side surfaces of the LED chip 12. In the present embodiment, the light emitting surface 123 is substantially coplanar with a top surface 131 of the side conductive layer 13. The side conductive layer 13 is made of a good heat conductive material. In the present embodiment, the side conductive layer 13 is made of copper. In the present embodiment, the side conductive layer 13 can be formed on the side surfaces of the LED chip 12 via electroplating.

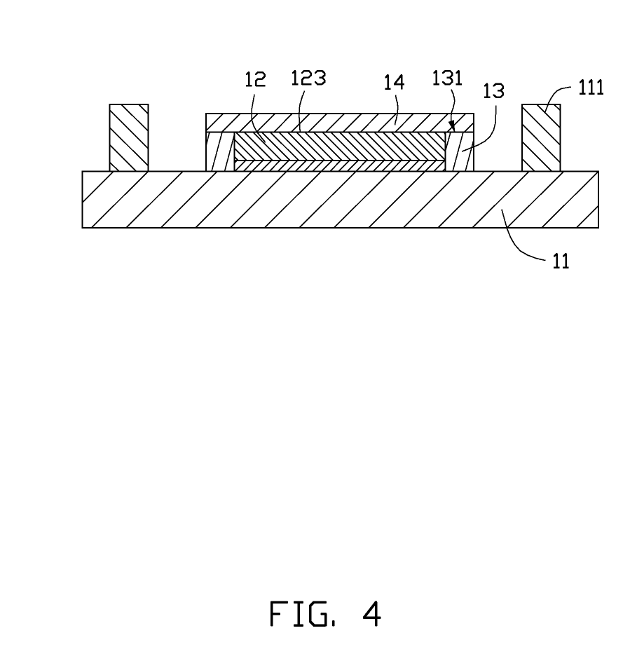

Step 4: referring to FIG. 4, forming a phosphor layer 14 on the light emitting surface 123 of the LED chip 12 and the top surface 131 of the side conductive layer 13 to seal the LED chip 12. The phosphor layer 14 can be excited by light from the LED chip 12 to generate a light with a wavelength different from that of the light generated by the LED chip 12.

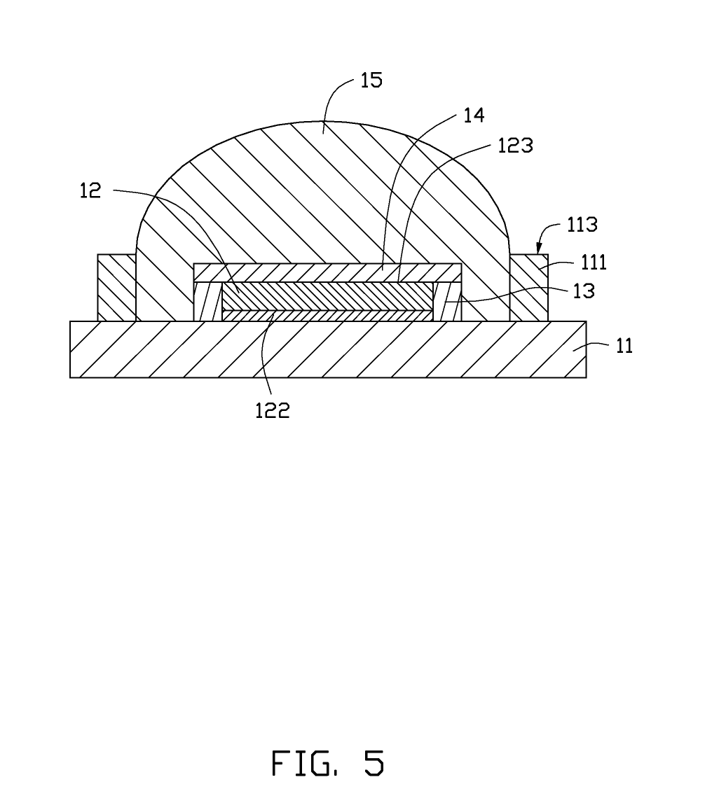

Step 5: referring to FIG. 5 and FIG. 1, forming a liquid heat conductive layer 15 covering the sealed LED chip 12, and mounting a sealing member 16 on the upper surface 113 of the side conductive plate 111 for sealing the liquid heat conductive layer 15. In the present embodiment, the sealing member 16 is made of transparent material, such as glass. The liquid heat conductive layer 15 is sealed in the sealing member 16 and covers the sealed LED chip 12. The liquid heat conductive layer 15 is made of a good heat conductive material. The liquid heat conductive layer 15 is liquid, and can transfer heat generated from the LED chip 12 to the ambient atmosphere via the sealing member 16.

In step 5, according to the present disclosure, the method can mount the sealing member 16 on the upper surface 113 of the side conductive plate 111 first, and then inject the liquid heat conductive layer 15 into the chamber sealed by the sealing member 16;

or it can form the liquid heat conductive layer 15 to cover the sealed LED chip 12 via glue dispensing first, and then mount the sealing member 16 on the upper surface 113 of the side conductive plate 111 to seal the liquid heat conductive layer 15 therein.

It is to be further understood that even though numerous characteristics and advantages have been set forth in the foregoing description of embodiments, together with details of the structures and functions of the embodiments, the disclosure is illustrative only; and that changes may be made in detail, especially in matters of shape, size, and arrangement of parts within the principles of the disclosure to the full extent indicated by the broad general meaning of the terms in which the appended claims are expressed.

What is claimed is:

1. An LED package, comprising:
a substrate;
an LED chip disposed on the substrate;
a sealing layer being formed on an outer surface of the LED chip whereby the LED is sealed from liquid;
a liquid heat conducting layer surrounding and covering the sealing layer on the LED chip; and
a sealing member arranged on the substrate to cover and seal the liquid heat conducting layer therein.

2. The LED package of claim 1, wherein the sealing layer comprises a phosphor layer arranged on a light emitting surface of the LED chip, the phosphor layer being surrounded and covered by the liquid heat conducting layer.

3. The LED package of claim 2, wherein the phosphor layer converts light from the LED chip into a light with a different wavelength.

4. The LED package of claim 2, the sealing member further comprises a side heat conductive layer surrounding side surfaces of the LED chip.

5. The LED package of claim 4, wherein the phosphor layer, the side heat conductive layer and the substrate cooperatively seal the LED chip thereamong.

6. The LED package of claim 1, further comprising an annular side heat conductive plate arranged on the substrate, the sealing member engaged with an upper surface of the side heat conductive plate to seal the liquid heat conducting layer therein.

7. The LED package of claim 6, wherein the side heat conductive plate is integrally formed with the substrate as a single piece.

8. The LED package of claim 1, further comprising a connecting layer arranged between the substrate and the LED chip.

9. The LED package of claim 8, wherein the connecting layer is made of copper, aluminum or an alloy thereof.

10. The LED package of claim 1, wherein the sealing member is made of transparent material.

11. The LED package of claim 10, wherein the sealing member is made of glass.

12. A method for manufacturing a LED package, comprising:
providing a substrate;
mounting an LED chip on the substrate;
sealing an outer surface of the LED chip to make the LED chip be liquid-proof;
forming a liquid heat conductive layer covering the sealed LED chip; and
mounting a sealing member on the substrate to seal the liquid heat conductive layer therein.

13. The method of claim 12, wherein before mounting and sealing the LED chip on the substrate, further comprising a step of mounting an annular side heat conductive plate on the substrate, the sealing member being mounted on the side heat conductive plate.

14. The method of claim 12, wherein the LED chip is sealed by the substrate, an annular side heat conductive layer surrounding side surfaces of the LED chip, and a phosphor layer arranged on a light emitting surface of the LED chip.

15. The method of claim 14, wherein the annular side heat conductive layer is formed on the side surfaces of the LED chip by electroplating.

16. The method of claim 12, wherein the sealing member is made of transparent material.

17. The method of claim 16, wherein the sealing member is made of glass.

18. The method of claim 12, wherein before sealing the LED chip on the substrate, further comprises steps of forming a first metal layer on the substrate and forming a second metal layer on a bottom surface of the LED chip, the LED chip being mounted on the substrate via mounting the second metal layer on the first metal layer and connecting the second meal layer to the first metal layer by eutectic bonding.
